(19) United States
(12) Patent Application Publication
(10) Pub. No.: US 2026/0206389 A1
(43) Pub. Date: Jul. 16, 2026

(54) A METHOD OF MANUFACTURING A MONOLITHIC DISPLAY

(71) Applicant: SmartKem Limited, Manchester, Greater Manchester (GB)

(72) Inventors: Simon OGIER, Manchester (GB); Daniel SHARKEY, Manchester (GB); Chia Hung TSAI, Manchester (GB)

(73) Assignee: SmartKem Limited, Manchester, GT (GB)

(21) Appl. No.: 19/134,028

(22) PCT Filed: Nov. 29, 2023
(86) PCT No.: PCT/GB2023/053088

§ 371 Date: May 29, 2025

(30) Foreign Application Priority Data
Nov. 30, 2022 (GB) 2218033.5

(51) Int. Cl. H10H 29/49; H10H 29/01; H10H 29/80; H10K 10/46

(52) U.S. Cl. CPC H10H 29/49; H10H 29/012; H10H 29/034; H10H 29/0364; H10H 29/8421; H10K 10/46

(57) ABSTRACT

A method of fabricating a monolithic micro-LED display component (2), the method comprising: depositing an LED (210) on a top surface (205a) of a substrate (205); depositing a base layer (240) over the LED (210), the base layer (240) forming a planar layer isolating the LED (210); processing an organic thin film transistor (260), OTFT, on the base layer (240) by depositing source and drain electrodes (256, 258) and an active channel comprising an organic semiconducting layer (262); and after processing of the OTFT (260), etching a base layer via (242, 244), the base layer via (242, 244) comprising a via through the base layer (240) to allow a connection between the LED (210) and the OTFT (260).

### FIELD OF THE INVENTION

The present invention relates to the manufacture of monolithic micro-LED displays.

### BACKGROUND

Micro-LED displays are an emerging flat-panel display technology, which use an array of microscopic LEDs for forming individual pixels. Micro-LED displays have many advantages over earlier liquid crystal displays (LCDs). For example, since the LEDs are only powered when a pixel is illuminated and can be completely turned off at other times, micro-LED displays are much more energy efficient, and have a better contrast ratio. Furthermore, micro-LED displays have a faster response time, thus making them more appropriate for augmented reality (AR) and virtual reality (VR) applications, where high pixel density and high frame rates are particularly useful.

Micro-LED displays are often made by transferring micro-LEDs from a source wafer onto a receiver substrate (the display backplane). This allows an RGB display to be made from individual red, green, and blue source micro-LED wafers. As an alternative to the above, one way to produce micro-LED displays with a very high resolution is to process the backplane directly on top of the micro-LEDs on the source wafer, thereby producing a monolithic display. For example, a sapphire substrate may form the bottom layer of the monolithic display, with a micro-LED and a thin film transistor (TFT) deposited on top. Vias are formed between the TFT and the micro-LED to allow the TFT to control the micro-LED.

One challenge with this approach is that the materials in the TFTs (such as LTPS) are processed at high temperatures which may damage the other components (e.g. the micro-LEDs and connections) that are already part of the backplane. It has been considered to use organic thin film transistors (OTFTs), which may be deposited over the micro-LED at a much lower temperature than inorganic TFTs. While this may reduce damage to other layers, deposition of OTFTs may present further difficulties.

For example, during deposition of the OTFT, the organic materials may fall into the vias that form the connection to the micro-LED. Particularly, given that these vias can be deep, subsequent etching may not completely remove this material from within the vias. Residual material in the vias may cause defects in the resulting device, such as inhibiting uniform coating of other layers deposited on top of the vias.

While micro-LED displays are an important example of a technology that suffers from the above manufacturing challenges, the same problems are also present when using other types of optoelectronic device such as LEDs or photodiodes. In particular, any technology that requires processing of connections or other types of circuitry, particularly OTFTs, over deposited optoelectronic devices will face similar challenges.

Therefore, it is an object of the present invention to address one or more of the problems described above.

### SUMMARY OF INVENTION

According to a first aspect of the present invention there is provided a method of fabricating a monolithic micro-LED display component, the method comprising: depositing an LED on a top surface of a substrate; depositing a base layer over the LED, the base layer forming a planar layer isolating the LED; processing an organic thin film transistor, OTFT, on the base layer by depositing source and drain electrodes and an active channel comprising an organic semiconducting layer; and after processing of the OTFT, etching a base layer via, the base layer via comprising a via through the base layer to allow a connection between the LED and the OTFT.

Advantageously, by processing the OTFT on a layer that isolates the LED, the etching away of organic layers may be performed more consistently. As used herein, the term “isolates” preferably connotes that no vias are formed through the base layer before processing of the OTFT on the base layer. In other words, the base layer is continuous during processing of the OTFT on the base layer. As used herein, the term “continuous” preferably connotes that the base layer is substantially flat and/or does not contain holes such as vias. For example, if vias were instead formed through the base layer prior to processing of the OTFT, it may be difficult to remove organic material that is deposited within the vias during subsequent processing of the OTFT. Typically, the vias that connect to the LED can be deep, which makes it particularly difficult to remove organic material contained therein. Where unwanted organic material is present, there may be imperfections in the deposition of subsequent layers, such as a further passivation layer (which may be deposited over and around the OTFT). For example, the presence of unwanted organic material may lead to de-wets in the passivation layer, such as due to the Cytop® dielectric residue. Where the passivation layer is deposited on the OTFT, one or more passivation layer vias may be etched through the passivation layer. At least one of the passivation layer vias may continue through the base layer to provide the base layer via.

The method preferably further comprises depositing a top contact layer (e.g. an OTFT contact layer) where the top contact layer provides a connection between the LED and the OTFT through the base layer via.

The monolithic micro-LED display component may be a “bottom-emission” display component, where light from the LED is emitted in a downward direction (e.g. through the substrate). Alternatively, the monolithic LED display component may be a “top-emission” display component, where light from the LED travels upwards (i.e. away from the substrate).

As used herein, the terms “top”, “bottom”, “above”, and “below” refer to directions and relative positions as depicted in the figures. It will be appreciated that these terms do not require than any of the embodiments described herein may only be operated in a particular orientation. The term “top” indicates the growth direction, i.e. the direction of growth relative to a substrate (which the device may or may not have been removed from). In other words, the growth direction is perpendicular to a plane defined by the substrate, LED, and/or the OTFT. It will be appreciated, that the LED may be any other kind of optoelectronic device, such as a photodiode. Furthermore, unless explicitly specified otherwise, terms such as “located”, “positioned”, “disposed” are merely intended to express relative position of two components or layers, and do not exclude other components from being located between said two components or layers.

The base layer is a dielectric layer that isolates a backgate layer of the OTFT (below the base layer), from the organic semiconducting layer and the source and drain electrodes (above the base layer). Preferably the chemistry of the base layer is matched to the organic semiconducting layer to allow for uniform morphology of the organic semiconducting layer. The base layer may be an organic cross-linked layer, where the chemistry is preferably selected such that it is free from residual ionic contamination that may dope the OTFT under bias stress conditions. The base layer may be an acrylate polymer. The base layer may be selected from those described in WO 2020/002914 A1. The base layer is preferably resistant to organic solvents. The base layer may have a thickness of 10 nm to 10 μm, preferably 100 nm to 1 μm.

The OTFT may be processed at a region on the base layer that overlaps the LED, at least partially. In other words, the OTFT overlaps the LED when viewed along the growth direction; i.e. from the top or bottom of the LED display component. In this way, performance of the micro-LED display component is improved when configured as a “bottom emission” display component. Since the OTFT does not need to be positioned so as not to obstruct light from the LED, the OTFT may cover a larger area of the display component. This may allow the OTFT to provide more current, and/or may allow a larger LED to be used.

Alternatively, where the micro-LED display component is configured as a “top emission” display component, the LED and the OTFT may be located at non-overlapping regions in the display component, so that the OTFT does not block light from the LED travelling in the upward direction.

Prior to depositing the base layer, the method may further comprise: depositing a planarization layer over the LED; etching a planarization layer via through the planarization layer; depositing an intermediate contact layer on the planarization layer, such that the intermediate contact layer is connected to the LED through the planarization layer via; the method further comprising depositing the base layer over the planarization layer and intermediate contact layer.

The step of etching the base layer via may comprise etching a via through the base layer to provide a connection to the intermediate contact layer, the method further comprising depositing an OTFT contact layer providing a connection between the OTFT and the intermediate contact layer, such that the OTFT is connected to the LED through the intermediate contact layer.

The method may further comprise: depositing a passivation layer over the base layer prior to etching the base layer via; etching one or more passivation layer vias through the passivation layer; wherein continued etching of at least one passivation layer via provides the base layer via; and wherein the OTFT contact layer is deposited into the passivation layer vias to connect the LED to the OTFT through the intermediate contact layer.

The planarization layer may have a thickness such that a portion of the planarization layer that is above the LED is at least 0.5 μm thick. Advantageously, this reduces the risk of shorting of the LED such as due to thinning of the planarization layer near the corners of the LED. Preferably, the planarization layer is greater than 1 μm, preferably greater than 2 μm thick.

The planarization layer provides a substantially planar surface upon which further layers are deposited. The planarization layer may provide a (first or middle) passivation layer. Optionally, a bottom passivation layer may be provided below the middle passivation layer, such as directly on the LED. Since the LED typically protrudes substantially from the substrate (e.g. about 3 to 4 μm), the planarization layer may be thick. Due to the thickness of the planarization layer, deep vias formed in the planarization layer prior to deposition of organic material may make it particularly challenge to remove the organic material at a later stage. As discussed above, organic material remaining in the vias may cause fabrication defects.

The intermediate contact layer may provide a backgate layer (i.e. backgate electrode) of the OTFT.

Alternatively, the backgate layer of the OTFT may be provided by a separate layer to the intermediate contact layer.

The intermediate contact layer may comprise a first region connected to a cathode of the LED by a first planarization layer via, and a second region connected to an anode of the LED by a second planarization layer via. The first region and the second region of the intermediate contact layer are preferably electrically isolated from each other. A third region of the intermediate contact layer (i.e. electrically isolated from the first and second regions) may provide the backgate layer of the OTFT. This may facilitate providing of an isolated backgate micro-LED display component. Alternatively, the first region or the second region may provide the backgate layer of the OTFT.

The intermediate contact layer and/or the backgate layer may provide a reflective layer such that light emitted by the LED in an upward direction is reflected by the reflective layer in a downward direction corresponding to a bottom surface of the LED. Advantageously, for a bottom-emission display, this improves the efficiency of the micro-LED display component and the display as a whole, since all, or a majority of the light, is emitted in a downward direction through a bottom side of the micro-LED display component. Alternatively, a reflective layer may be provided which is separate to the backgate layer and/or the intermediate contact layer.

Processing the OTFT may comprise depositing one or more dielectric layers on the organic semiconducting layer. The one or more dielectric layers may comprise an organic gate insulator and/or a sputter resistant layer. The organic gate insulator may be deposited on the organic semiconducting layer, and the sputter resistant layer may be deposited on the organic gate insulator. The sputter resistant layer may be UV cured. The sputter resistant layer is arranged to provide resistance to the organic gate insulator and organic semiconducting layer to sputter damage during subsequent steps (e.g., formation of a frontgate electrode). Processing the OTFT further comprises depositing a frontgate metal on the one or more dielectric layers. Processing the OTFT further comprises at least partially etching away one or more organic layers above the base layer. As used herein, the term “organic layers” may include layers such as the organic semiconducting layer, the organic gate insulator, and the sputter resistant layer, though may include different or additional organic layers. Preferably, the etching comprises dry etching. By etching away the organic layers, an OTFT is formed at a particular region upon the base layer.

The base layer may isolate the LED during at least one, and preferably all of the OTFT processing steps recited above. Where processing of the OTFT includes additional steps and/or different steps to those described above and herein, the base layer preferably isolates (i.e., remains continuous without etching vias) until completion of the processing of the OTFT. In other words, the base layer preferably isolates (remains continuous) during deposition of the organic layers of the OTFT.

The method may further comprise: depositing a passivation layer over the OTFT and the base layer, and etching said passivation layer to form one or more passivation layer vias.

As used herein, the planarization layer between the LED and the base layer may be referred to as a first (or middle) passivation layer, and the passivation layer deposited over the OTFT may be referred to as a second (or top) passivation layer (or second planarization layer). A bottom passivation layer may be provided below the middle passivation layer, such as directly on the LED. The one or more vias through the (second) passivation layer may extend to the source and drain electrodes of the OTFT. The one or more vias through the (second) passivation layer may extend to the frontgate electrode of the OTFT.

The (second) passivation layer may have a thickness of about 2 μm. The first and/or second passivation layers may be an acrylate-based material, such as SmartKem material PL-02-02-01.

The base layer via may be formed by continuing etching of at least one of the passivation layer vias through the base layer.

In other words, the one or more passivation layer vias also extend through the base layer to provide base layer vias. The base layer via preferably extends to the intermediate contact layer. Preferably, the (second) passivation layer and the base layer are etched in succession, and more preferably in the same etching step. Alternatively, the etching of the (second) passivation layer and the base layer may be done in different steps. In this way, a connection may be formed between the LED and the OTFT through the intermediate contact layer.

The method may further comprise depositing an OTFT contact layer into the one or more passivation layer vias. The OTFT contact layer facilitates electrical connections through the vias. For example, the OTFT contact layer may connect the drain electrode of the OTFT to the second region of the intermediate contact layer via an upper surface of the (second) passivation layer. In this way, the drain electrode may be connected to the anode of the LED. Alternatively, the source electrode may connect to the anode. The OTFT contact layer may provide a connection to the frontgate electrode of the OTFT. The OTFT contact layer may provide a connection to the cathode of the LED, via the first region of the intermediate contact layer.

The method may further comprise growing the LED on a source wafer, and subsequently transferring the LED from the source wafer to the substrate using an intermediate substrate. In other words, the LED is deposited on a top surface of a substrate using the intermediate layer. Advantageously, only the required amount of source wafer is required to form the LED, and the source wafer may be reused to manufacture further LEDs. The LEDs may be transferred onto the substrate to align with a corresponding quantum-dot colour conversion material. In this way, and LED with a certain colour can be used to produce a pixel (or sub-pixel) with a different colour, thereby allowing manufacturing of a colour (e.g. RGB) display.

The method may further comprise detaching the substrate from the layers above the substrate.

The OTFT may be processed, at least partially, using a solution processing technique. For example, the organic semiconducting layer may be deposited using solution processing. Particularly when using a wet technique such as solution processing, the organic layers may be more likely to fall within any vias formed through the base layer. Therefore, when using solution processing it is particularly advantageous to etch the base layer vias after processing of the OTFT.

alternatively or additionally, the OTFT may be processed using a vacuum deposition technique.

According to another aspect of the present invention, there is provided a monolithic micro-LED display component, comprising: an LED having a top surface and an opposing bottom surface; a planar base layer formed above the top surface of the LED; an organic thin film transistor, OTFT, processed at least partially on an upper surface of the base layer; a passivation layer deposited on the OTFT; and a base layer via etched through both the base layer and the passivation layer, whereby to allow an electrical connection between the LED and the OTFT.

Since the base layer via is etched through both the base layer and the passivation layer, this via must be formed after the OTFT has been processed on the base layer. As described above, forming a base layer via after processing of the OTFT prevents organic material from being deposited into existing vias, which can cause defects when subsequent layers are deposited on top.

The integrated circuit may further comprise a substrate having a top surface and an opposing bottom surface, wherein the LED is formed on the top surface of the substrate.

The monolithic micro-LED display component may further comprise an intermediate contact layer formed on a lower surface of the base layer and electrically connected to the LED, wherein the base layer via is connected to the intermediate contact layer. The base layer and/or the intermediate contact layer may be deposited upon a planarization layer formed over the top surface of the LED. The intermediate contact layer may provide the backgate layer of the OTFT.

As used herein, the term “formed” preferably indicates that the base layer is located above the top surface of the LED. As used herein, the term “processed” preferably indicates that the OTFT is located on the upper surface of the base layer. As used herein the term “deposited” preferably indicates that the passivation layer is located on the OTFT. The term “etched” preferably indicates that the via is passes through a particular layer, which may be achieved using an etching process. According to another aspect of the present invention, there is provided a monolithic micro-LED display component, comprising: an LED having a top surface and an opposing bottom surface; a planar base layer located above the top surface of the LED; an organic thin film transistor, OTFT, located at least partially on an upper surface of the base layer; a passivation layer located on the OTFT; and a base layer via passing through both the base layer and the passivation layer, whereby to allow an electrical connection between the LED and the OTFT.

According to another aspect of the present invention there is provided a monolithic micro-LED display component, comprising: an LED having a top surface and an opposing bottom surface; a planar base layer formed above the top surface of the LED; an organic thin film transistor, OTFT, processed at least partially on an (e.g., continuous) upper surface of the base layer; and a base layer via etched through the base layer (e.g., through any organic material remaining after processing of the OTFT), whereby to allow an electrical connection between the LED and the OTFT. As described above, forming a base layer via after processing of the OTFT prevents organic material from being deposited into existing vias, which can cause defects when subsequent layers are deposited on top.

According to another aspect of the present invention there is provided a monolithic micro-LED display component, comprising: an LED having a top surface and an opposing bottom surface; a planarization layer formed over the top surface of the LED; an intermediate contact layer deposited on the planarization layer, such that the intermediate contact layer is connected to the LED through the planarization layer; a planar base layer formed over the intermediate contact layer; an organic thin film transistor, OTFT, processed at least partially on an upper surface of the base layer; and a base layer via etched through the base layer to the intermediate contact layer, whereby to allow an electrical connection between the LED and the OTFT.

The intermediate contact layer may provide the backgate layer of the OTFT. The intermediate contact layer may be connected to the LED via a planarization layer via etched through the planarization layer.

Since the problems occurring during the manufacture of existing display components are present regardless of the type of LED being used, it will be appreciated that any of the aspects described above and herein may be applied to other LED display components as well as micro-LED display components. Therefore, it will be appreciated that the methods and devices described herein may use LEDs of any size. As used herein the term “LED” may be used to refer both to micro-LEDs and also LEDs with other dimensions.

Furthermore, while the discussion above generally relates to the use of light emitting optoelectronic devices such as an LEDs (i.e., to provide an LED display component), it will be appreciated that the LED could be replaced with a light detecting optoelectronic device such as a photodiode (i.e., to provide a photodetector array). In this way, a monolithic photodetector array may be provided that can be used to sense incoming light, rather than to emit light. In other words, the direction of light propagation and operation of the device is effectively reversed in order to provide a light detector. Any reference made above to the direction of propagation of light in relation to display components can be reversed when referring to photodetector arrays, though the manufacturing steps and corresponding advantages of the above manufacturing process remain substantially the same. For example, the reflective layer not only improves the proportion of light emitted by a display, but also improves the proportion of light detected by a photodetector array. Where photodiodes are used, the OTFTs may instead be operated to provide a readout of the electrical signals from the photodiodes. GaN or other inorganic diode arrays may be linked with OTFT backplanes in a similar manner to the displays described above and herein. The skilled person having the benefit of this disclosure would be aware of any modifications to the display components described above that would be required in order to instead provide a photodetector array.

According to another aspect of the present invention there is provided a method of fabricating a monolithic LED display component, the method comprising: depositing an LED on a top surface of a substrate; depositing a base layer over the LED, the base layer forming a planar layer isolating the LED; processing an organic thin film transistor, OTFT, on the base layer by depositing source and drain electrodes and an active channel comprising an organic semiconducting layer; and after processing of the OTFT, etching a base layer via, the base layer via comprising a via through the base layer to allow a connection between the LED and the OTFT.

According to another aspect of the present invention, there is provided a monolithic LED display component, comprising: an LED having a top surface and an opposing bottom surface; a planar base layer formed above the top surface of the LED; an organic thin film transistor, OTFT, processed at least partially on an upper surface of the base layer; a passivation layer deposited on the OTFT; and a base layer via etched through both the base layer and the passivation layer, whereby to allow an electrical connection between the LED and the OTFT.

It will be understood by a skilled person that any apparatus feature described herein may be provided as a method feature, and vice versa. It will also be understood that particular combinations of the various features described and defined in any aspects described herein can be implemented and/or supplied and/or used independently.

Moreover, it will be understood that the present invention is described herein purely by way of example, and modifications of detail can be made within the scope of the invention.

### BRIEF DESCRIPTION OF DRAWINGS

One or more embodiments will now be described, purely by way of example, with reference to the accompanying figures, in which:

FIGS. 1A to 1P depict a first method of manufacturing a monolithic display component;

FIGS. 2A and 2B depict defects that may occur during the method in FIG. 1A to 1P;

FIGS. 3A to 3J depict a preferred method of manufacturing a monolithic display component, according to the present invention;

FIG. 4 depicts an embodiment of a monolithic display component that may be formed using the method shown in FIGS. 3A to 3J; and

FIGS. 5A to 5K depict a method of manufacturing a monolithic display component, according to the present invention.

### DETAILED DESCRIPTION

In the following description and accompanying drawings, corresponding features may preferably be identified using corresponding reference numerals to avoid the need to describe said common features in detail for each and every embodiment.

Methods of manufacturing monolithic micro-LED display components 1, 2, 3, 4 will now be described in detail. Generally, the methods involve depositing (or growing) at least one LED and at least one organic thin film transistor (OTFT) on a substrate, with vias providing electrical connections therebetween.

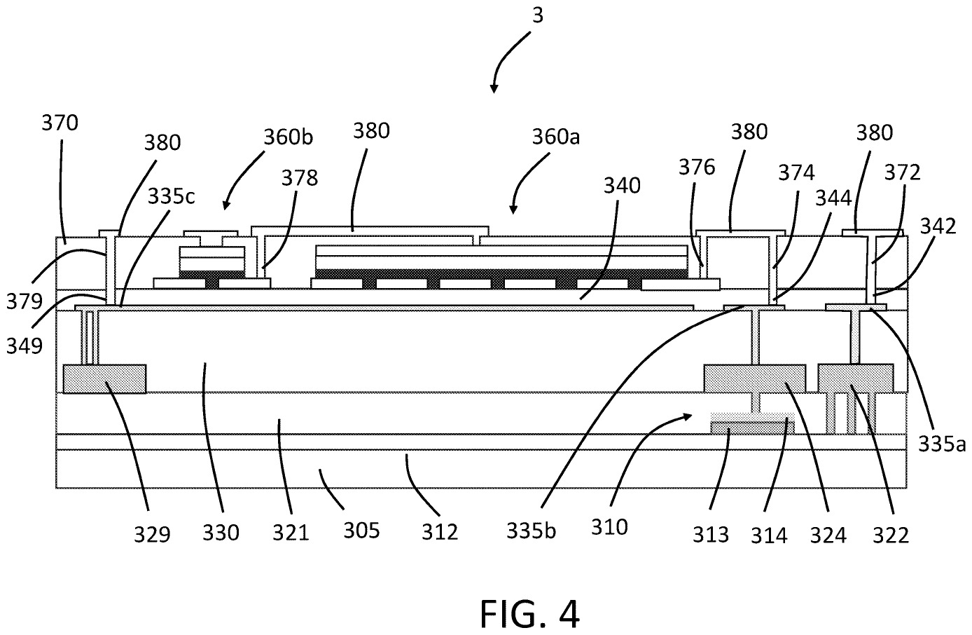

While the following description will generally describe the display components with reference to a single LED and a single OTFT, it will be appreciated that the display components may contain a large array of LEDs which each may have one or more respective OTFTs. For example, the array of LEDs may provide an array of pixels. Furthermore, each pixel of the display component may comprise sub-pixels that may be configured to emit light in predetermined colours, for example to provide an RGB display. It will also be appreciated that more than one OTFT may be provided for each LED, and that other components such as capacitors may be present. For example, each LED may have a corresponding switch TFT and a drive TFT, as described further in relation to FIG. 4.

Other components may be combined with the display components in order to provide a display device. For example, protective layers, frames, electrical connections and/or any other suitable components may be combined with the display component.

As used herein, the term “monolithic” connotes that the OTFT devices are deposited (or “grown”) on the substrate containing the LEDs rather than the LEDs being transferred to the substrate containing the OTFT devices. In this way, the substrate may be referred to as the “source wafer”. The deposition of the layers that form the LED components may be achieved in various ways, including a chemical vapour deposition (CVD) technique such as plasma-enhanced chemical vapour deposition (PECVD) or metalorganic chemical vapour deposition (MOCVD), an epitaxy technique such as metalorganic vapour-phase epitaxy (MOVPE) or molecular beam epitaxy (MBE), a vacuum deposition technique, a solution processing technique, and/or a mass transfer technique. These techniques allow thin films (or “layers”) of material to be deposited on the substrate in order to form the monolithic micro-LED display component. Throughout the process, portions of the layers may be selectively removed in a process known as patterning, which may be achieved by (dry) etching. In this way, it is possible to electrically isolate regions of each layer from each other and to form channels (e.g. vias) for electrical pathways through the layers.

Preferably, the display components described herein are configured as “bottom-emission” display components, where light from the LED is emitted in a downward direction (i.e. through the substrate). In this configuration, the OTFT may be located at a region that overlaps the LED when viewed along the growth direction, since the OTFT does not need to be positioned so as not to obstruct light from the LED. This may allow the LED and/or the OTFT to occupy a larger area of the display component, which may allow the OTFT to provide more current. When configured as a bottom emission display component, the substrate is preferably at least partially transparent; alternatively or additionally, the substrate may be removed at the end of the manufacturing process. While a bottom emission display component is preferable, the display component may be a top emission display component, where the LED and the OTFT are located at non-overlapping regions in the display component so that the OTFT does not block light from the LED travelling in the upward direction.

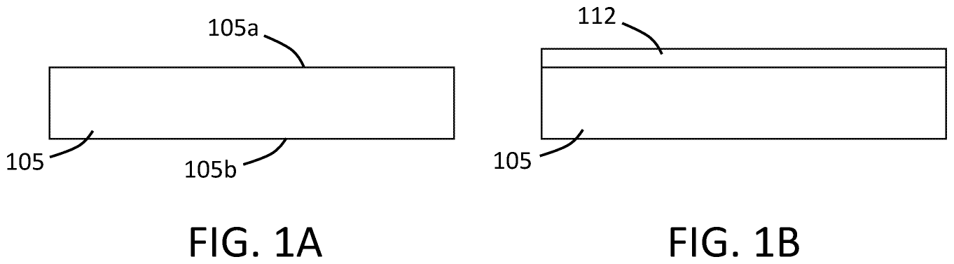

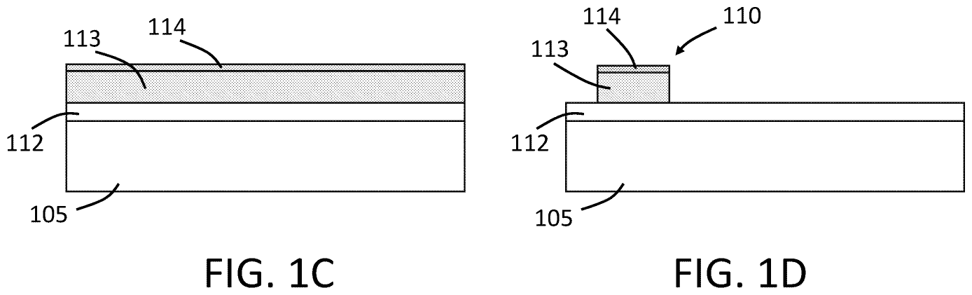

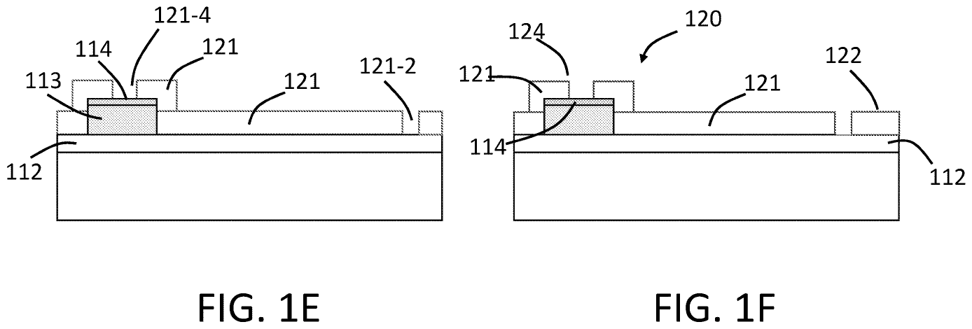

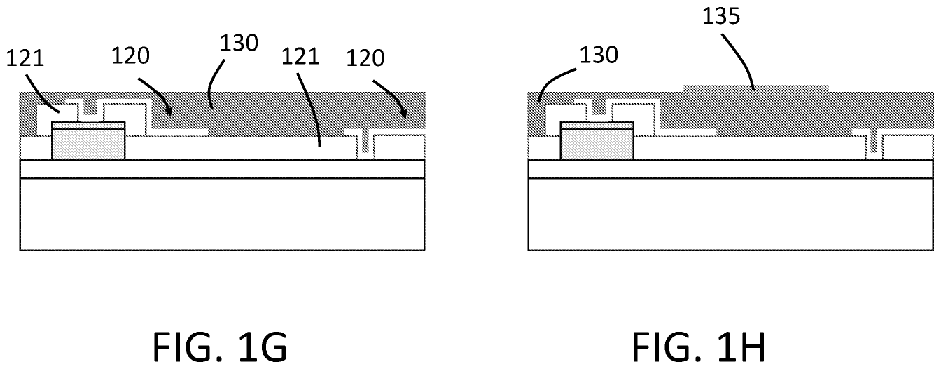

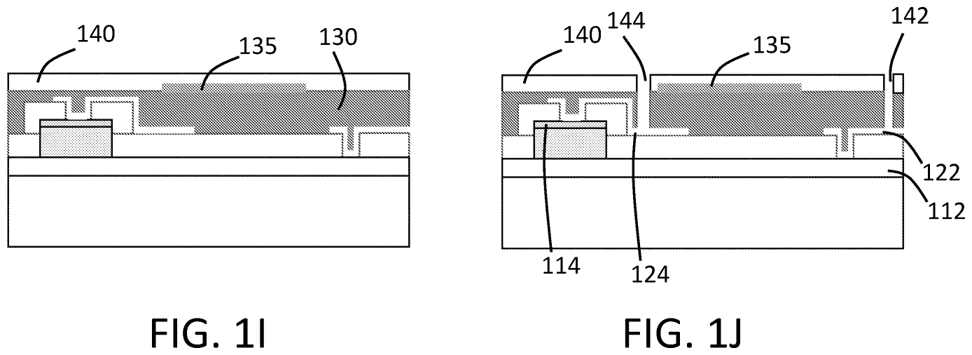

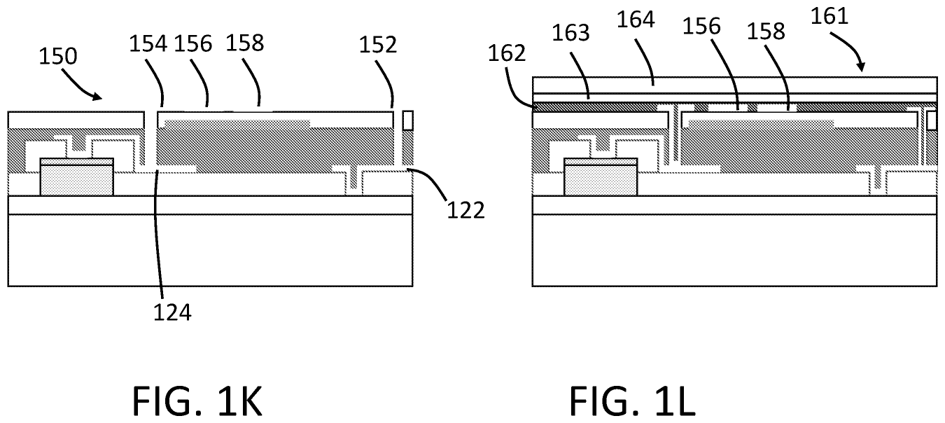

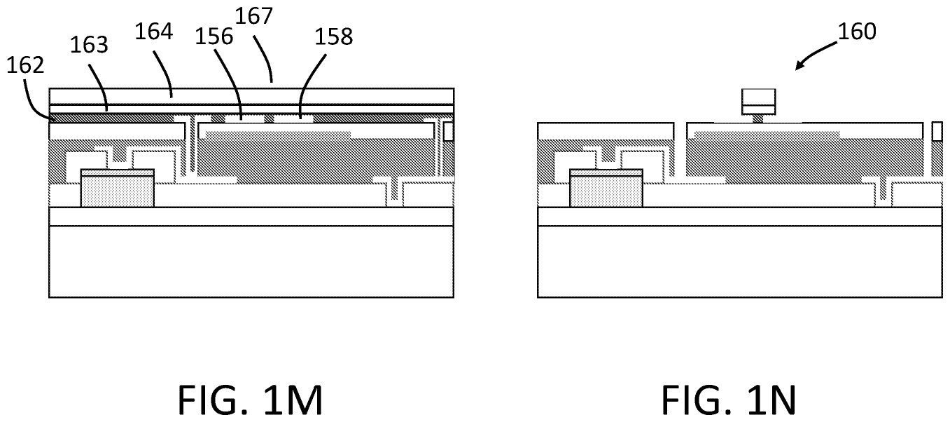

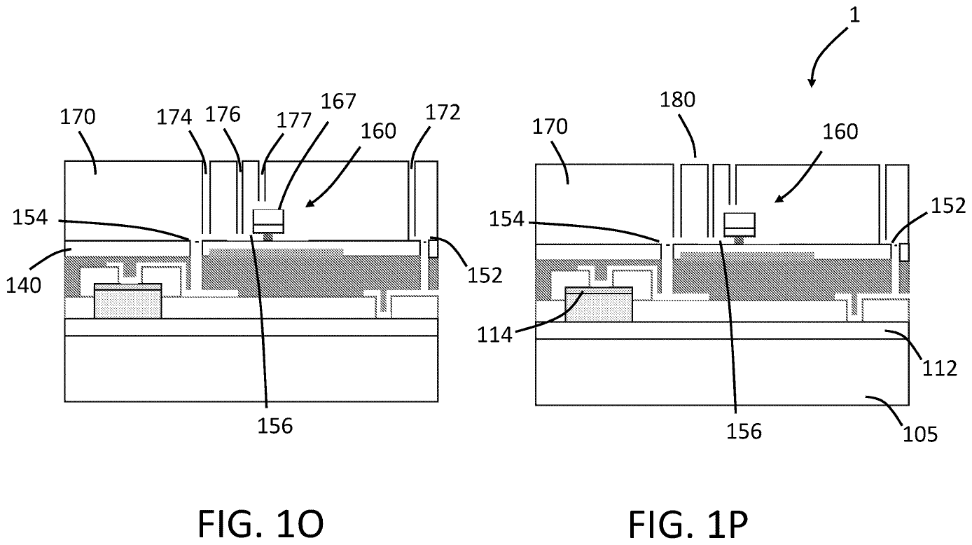

A first method of manufacturing a monolithic micro-LED display component 1 will now be described in relation to FIGS. 1A to 1P.

In FIG. 1A, a substrate 105 is provided, which has a top surface 105a and an opposing bottom surface 105b. The substrate 105 may be a sapphire wafer, though other materials such as zinc oxide, silicon oxide or silicon carbide may be used. The substrate layer 105 is preferably polished on the bottom surface 105b so as not to affect the quality of the image from the display component 1. The substrate 105 may be polished on the top surface 105a or may be patterned on the top surface 105a to reduce stress on the layers grown on top of the substrate 105. More specifically, the substrate 105 may be a c-oriented cone-shaped patterned sapphire substrate (CPSS), or may be a conventional unpatterned planar sapphire substrate (USS).

Subsequently, a cathode layer 112 may be deposited on the top surface 105a of the substrate 105, as shown in FIG. 1B. The cathode layer 112 may comprise n-Gallium Nitride (n-GaN), which may be grown on top of the sapphire substrate 105 due to appropriate lattice matching of the GaN and the sapphire crystal.

In FIG. 1C, an LED structure 113 is deposited on the cathode layer 112. The LED structure 113 may comprise a Micro Quantum Well (MQW) structure including layers of InGaN and GaN. For example, the LED structure 113 may comprise a GaN nucleation layer (e.g. 25 nm thick), an undoped GaN layer (e.g. 2.5 μm thick), a highly doped n-type GaN layer (e.g. 2 μm thick), a plurality of pairs of InGan (4.6 nm)/GaN (5.2 nm) MQWs (e.g. 13 pairs), a p-type AlGaN electron blocking layer (e.g. 25 nm thick), and a Mg-doped GaN layer (e.g. 100 nm thick). It will be appreciated that the layers and materials described above are merely exemplary, and that other layers and materials may be used.

Additionally, an anode layer 114 is deposited on top of the LED structure 113. The anode layer 114 may be Indium Tin Oxide (ITO). The anode layer 114 may be deposited using an e-beam evaporator.

In FIG. 1D, the LED structure 113 and the anode layer 114 are etched to provide an LED 110 at a particular location on the cathode layer 112. The etching may be dry etching, such as using an inductively coupled plasma (ICP) etching technique. While only one LED 110 is shown in FIG. 1D it will be appreciated that many LEDs may be provided such as to provide a display component 1 with many pixels and/or to provide sub-pixels with different colours. Accordingly, the cathode layer 112 may be shared across many, any optionally all LEDs on the display component 1, which may simplify manufacturing of the display component 1. Alternatively, the cathode layer 112 may be patterned to provided separate cathode layers 112 such as for each pixel of the display component 1.

In FIG. 1E, a bottom passivation layer 121 is deposited and patterned on the LED 110 and the cathode layer 112. The bottom passivation layer 121 may comprise SiO₂. The bottom passivation layer 121 may be patterned to provide a first via 121-2 to the cathode layer 112, and a second via 121-4 to the anode layer 114.

In FIG. 1F, a bottom contact layer 120 is deposited on the bottom passivation layer 121 in order to provide electrical connections through the vias 121-2, 121-4 in the bottom passivation layer 121 to the LED 110. More specifically, the bottom contact layer 120 has a first bottom contact portion 122 that provides an electrical connection to the cathode layer 112 through the first via 121-2, and a second bottom contact portion 124 that provides an electrical connection to the anode layer 114 through the second via 121-4. The bottom contact layer 120 is preferably a metal such as gold.

In FIG. 1G, a planarization layer 130 is deposited over the layers below, thereby providing a planar surface upon which to deposit subsequent layers. More specifically, the planarization layer 130 is deposited over the bottom contact layer 120 and the bottom passivation layer 121. This planarization layer 130 may be a passivation layer, which may be referred to as a middle passivation layer 130, or a “first” passivation layer 130. Since the LED 110 may protrude by about 3 to 4 μm from the substrate 105, the planarization layer 130 needs to have sufficient thickness to prevent shorting of the LED 110 such as due to thinning of the planarization layer 130 near the corners of the LED 110. The planarization layer 130 may have a thickness such that the portion of the planarization layer 130 that is above the LED 110 is at least 0.5 μm thick. The planarization layer 130 may have a thickness greater than 1 μm, preferably greater than 2 μm. The planarization layer 130 may be an acrylate-based material, such as SmartKem material PL-02-02-01.

In FIG. 1H, an intermediate (contact) layer 135 is deposited and patterned on the planarization layer 130. As discussed later, the intermediate layer 135 may be a backgate layer that provides a backgate electrode of the OTFT 160. The intermediate layer 135 may be a metal such as gold or molybdenum-aluminium-molybdenum (MAM).

In FIG. 1I, a base layer 140 is deposited over the planarization layer 130 and the intermediate layer 135. The base layer 140 creates a planar surface for subsequent layers, and also separates the backgate layer 135 from the other parts of the OTFT 160. The base layer 140 is a dielectric layer, and the chemistry of the base layer 140 is preferably matched to an organic semiconducting layer 162 of the OTFT 160 to allow for uniform organic semiconducting layer 162 morphology. The base layer 140 may be an organic cross-linked layer, where the chemistry is preferably selected such that it is free from residual ionic contamination that may dope the OTFT 160 under bias stress conditions. The base layer 140 may be an acrylate polymer. The base layer 140 may be selected from those described in WO 2020/002914 A1. The base layer 140 is preferably resistant to organic solvents. The base layer 140 may have a thickness of 10 nm to 10 μm, preferably 100 nm to 1 μm.

In FIG. 1J, vias 142, 144 are etched through the base layer 140 and the planarization layer 130 in order to allow an electrical connection to the LED 110. More specifically, a first planarization via 142 is etched to allow an electrical connection to the first bottom contact portion 122 thereby connecting to the cathode layer 112, and a second planarization via 144 is etched to allow an electrical connection to the second bottom contact portion 124 thereby connecting to the anode layer 114.

In FIG. 1K, a middle contact layer 150 is deposited on the base layer 140. The middle contact layer 150 provides the drain electrode 156 and source electrode 158 of the OTFT 160. The drain electrode 156 and the source electrode 158 are separated by a distance that corresponds to the length of an active channel of the OTFT 160. The middle contact layer 150 also fills the first and second planarization vias 142, 144 thereby providing a first middle contact portion 152 connected to the first bottom contact portion 122, and a second middle contact portion 154 connected to the second bottom contact portion 124. The middle contact layer 150 may be a metal such as gold.

In FIG. 1L, the OTFT 160 is processed. Processing of the OTFT 160 may include depositing one or more organic layers 161. This includes depositing an organic semiconducting layer 162 between the drain electrode 156 and the source electrode 158 in order to form an active channel. Depositing the OTFT 160 may include depositing one or more dielectric layers on the organic semiconducting layer 162. For example, an organic gate insulator 163 may be deposited on the organic semiconducting layer 162. The selection of the material for the organic gate insulator 163 and its associated permittivity determines the carrier density in the active channel and influences device hysteresis. A sputter resistant layer 164 may be deposited on the organic gate insulator 163. The sputter resistant layer 164 may be UV cured. The sputter resistant layer 164 is arranged to provide resistance to the organic gate insulator 163 and the organic semiconducting layer 162 to sputter damage during subsequent steps. The sputter resistant layer 164 is also preferably selected to enable the deposition of a wide range of gate electrode materials.

In FIG. 1M, a frontgate electrode 167 is deposited on the one or more dielectric layers, more specifically on the sputter resistant layer 164. In FIG. 1N, the organic layers 161 are etched in order to provide the OTFT 160 at a particular region on the base layer 140. The etching may be dry etching. As will be discussed later in more detail, it may be difficult to remove all the organic material 161 from within the vias 142, 144, which may lead to defects during subsequent steps.

In FIG. 1O, a passivation layer 170 is deposited over the OTFT 160 and the base layer 140. This passivation layer 170 may be referred to as a top passivation layer 170 or a “second” passivation layer 170. The top passivation layer 170 may have a thickness of about 2 μm. The top passivation layer 170 may be an acrylate-based material, such as SmartKem material PL-02-02-01.

One or more vias may be etched through the top passivation layer 170 in order to allow electrical connections to the OTFT 160 and the LED 110. More specifically, a first passivation layer via 172 is etched to allow a connection to the first middle contact portion 152, a second passivation layer via 174 is etched to allow a connection to the second middle contact portion 154, a third passivation layer via 176 is etched to allow a connection to the drain electrode 156 of the OTFT 160, and a fourth passivation layer via 177 is etched to allow a connection to the frontgate electrode 167 of the OTFT 160.

In FIG. 1P, a top contact layer 180 (or “OTFT contact layer”) is deposited onto the top passivation layer 170 and into the vias in order to provide electrical connections through the vias. In this example, the top contact layer 180 provides a connection to the first middle contact portion 152 through the first passivation layer via 172, thereby providing a connection to the cathode 112 of the LED 110. The top contact layer 180 also connects the drain electrode 156 of the OTFT 160 to the second middle contact portion 154 through the second passivation layer via 174 and third passivation layer via 176, thereby connecting the drain electrode 156 to the anode 114 of the LED 110. The top contact layer 180 also provides a connection to the frontgate electrode 167 of the OTFT 160 through the fourth passivation layer via 177. The top contact layer 180 may be a metal such as gold.

Optionally, the substrate 105 may be detached from the layers above the substrate 105 (e.g. the cathode layer 112). The substrate 105 may be removed via any suitable etching technique or achieved by using a laser, such as by laser ablation. In this way, when the display component 1 is configured as a downward emission display component, light from the LEDs 110 does not have to pass through the substrate 105 thereby increasing efficiency of the display.

The OTFT 160 may be processed, at least partially, using a solution processing technique. For example, the organic semiconducting layer 162 may be deposited using solution processing. Alternatively or additionally, the OTFT 160 may be processed using a vacuum deposition technique.

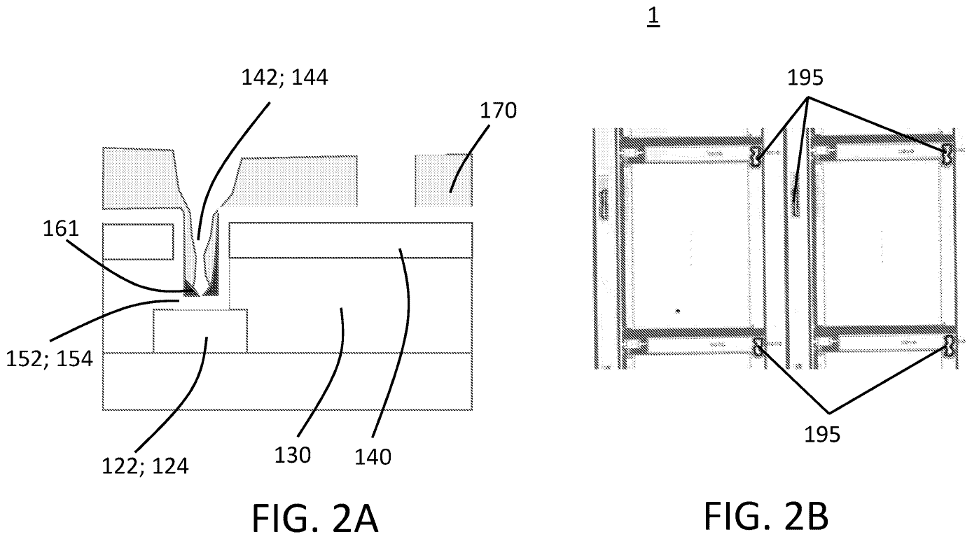

While the above method may be used to manufacture a monolithic micro-LED display component 1, it may lead to the following problems. FIG. 2A shows a close-up of one of the planarization vias 142, 144. As previously discussed in relation to FIG. 1J, these vias 142, 144 are etched through the base layer 140 and the planarization layer 130 in order to allow an electrical connection to the LED 110. However, during the subsequent deposition of the organic layers 161 of the OTFT 160 discussed in step 1L, the organic material 161 may enter the planarization vias 142, 144. While these organic layers 161 are etched away as described in relation to FIG. 1N, due to the depth of the planarization vias 142, 144, it is difficult to remove all of the organic material 161 from within the vias 142, 144. As a result, a residue is formed that may lead to defects during the subsequent deposition of the top passivation layer 170. More specifically, the material of the top passivation layer 170 may de-wet from out of the vias 142, 144 due to the Cytop® dielectric residue. FIG. 2B shows a top-down view of the display component 1, where a number of de-wets 195 have formed due to the process described above.

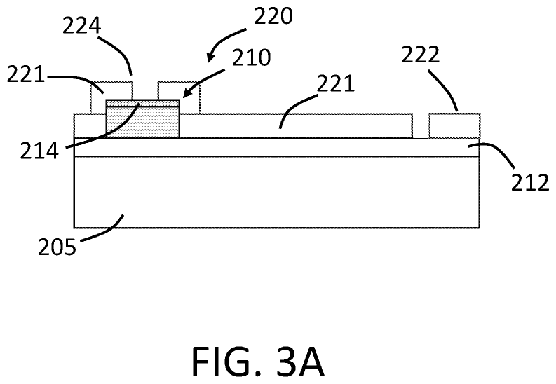

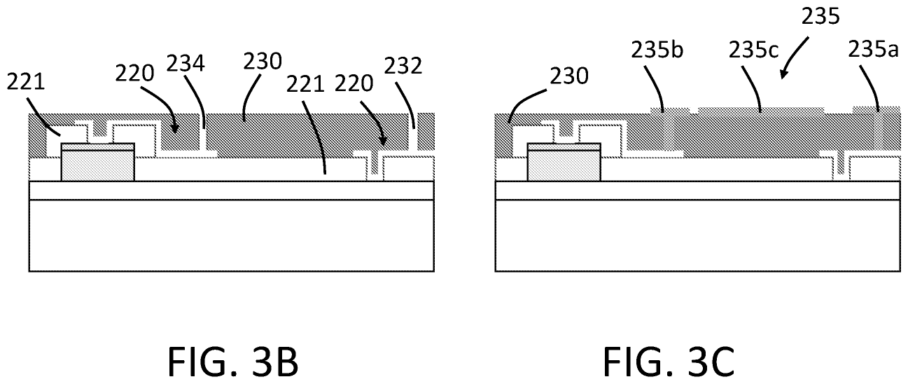

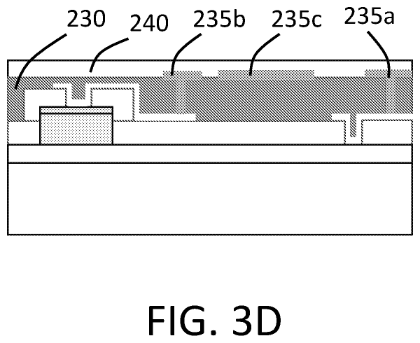

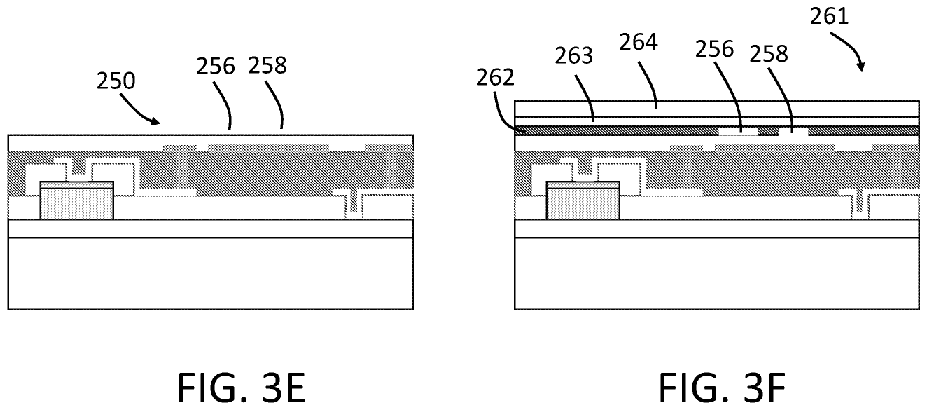

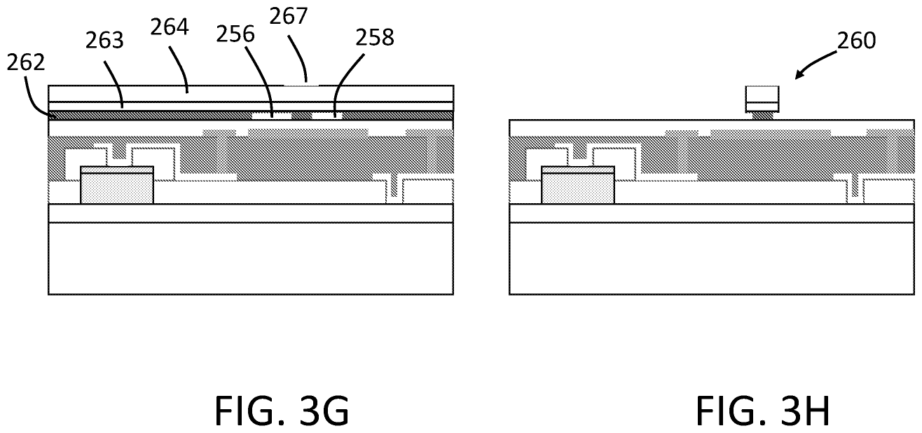

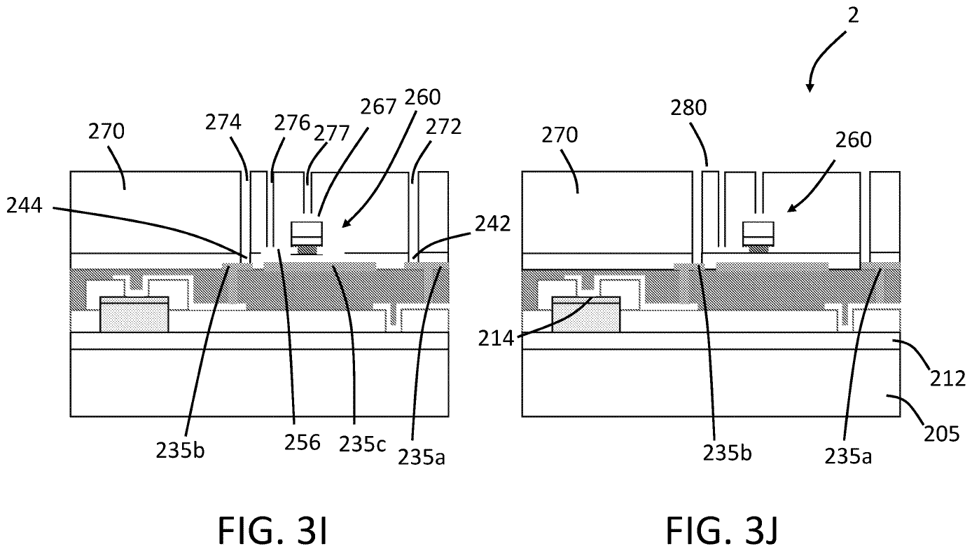

In order to address the problem above, a preferred method of manufacturing a monolithic display component 2 will now be described in relation to FIG. 3A to 3J. A number of the steps and features described in FIGS. 3A to 3J correspond to those described in relation to FIGS. 1A to 1P. Therefore, corresponding features are identified using corresponding reference numerals in order to avoid the need to describe these common features in detail again. It will be appreciated that any details discussed above, such as relating to materials, dimensions, properties of the layers, and/or manufacturing processes may also apply to the following preferred method.

Initially the method begins as already described in relation to FIGS. 1A to 1F. Accordingly, FIG. 3A shows the equivalent arrangement to FIG. 1F. In FIG. 3B, a planarization layer 230 is deposited over the layers below (i.e. over the LED 210), thereby providing a planar surface upon which to deposit subsequent layers. More specifically, the planarization layer 230 is deposited over the bottom contact layer 220 and the bottom passivation layer 221. This planarization layer 230 may be a passivation layer, which may be referred to as a middle passivation layer 230, or a “first” passivation layer 230.

As also shown in FIG. 3B, at least one planarization layer via may be etched through the planarization layer 230. More specifically, a first planarization layer via 232 is etched to allow an electrical connection to the first bottom contact portion 222, and a second planarization layer via 234 is etched to allow an electrical connection to the second bottom contact portion 224.

In FIG. 3C, an intermediate (contact) layer 235 is deposited and patterned on the planarization layer 230 and in the planarization layer vias 232, 234. More specifically, the intermediate layer 235 may have a first region 235a connected to the cathode 112 of the LED 110 by the first planarization layer via 232, and a second region 235b connected to the anode 114 of the LED 110 by the second planarization layer via 234. The intermediate layer 235 may also be a backgate layer that provides the backgate electrode of the OTFT 260. In this example, the intermediate layer 235 comprises a third region 235c that provides the backgate electrode of the OTFT 260. In this way, an isolated backgate micro-LED display component may be manufactured. Alternatively, the first and/or second regions 235a, 235b of the intermediate layer 235 may provide the backgate electrode of the OTFT 260.

When configured as a bottom emission display, the intermediate layer 235 may provide a reflective layer such that light emitted by the LED 210 in an upward direction is reflected by the reflective layer in a downward direction corresponding to a bottom surface of the LED 210. This improves the efficiency of the micro-LED display component 2 and the display as a whole, since all, or a majority of the light is emitted in a downward direction through a bottom side of the micro-LED display component 2. Therefore, the intermediate layer 235 may provide the backgate layer of the OTFT 260 and/or may provide a reflective layer. Alternatively, a reflective layer may be provided which is separate to the backgate layer and/or the intermediate layer 235. The reflective layer may be a metal layer and may comprise Al, Ag, Mo, and/or Au. A reflective layer may also be incorporated into the method described in relation to FIGS. 1A to 1P.

In FIG. 3D, a base layer 240 is deposited over the planarization layer 230 and the intermediate layer 235. The base layer 240 creates a planar surface for subsequent layers, and also separates the backgate layer 235c from the other parts of the OTFT 260. Accordingly, the base layer 240 isolates the LED 210 from layers on top such as the OTFT 260. The term “isolates” preferably connotes that no vias are formed through the base layer 240 before processing of the OTFT 260 on the base layer 240. In other words, the base layer 240 is continuous during processing of the OTFT 260 on the base layer 240.

In FIG. 3E, the drain electrode 256 and the source electrode 258 of the OTFT 260 are deposited on the base layer 240. These electrodes 256, 258 may be referred to as a middle contact layer 250, which is separate from the intermediate contact layer 235 described above.

In FIG. 3F, the OTFT 260 is processed. Processing the OTFT 260 may include depositing organic layers 261. This includes depositing an organic semiconducting layer 262. Depositing the OTFT 260 may include depositing one or more dielectric layers on the organic semiconducting layer 262. For example, an organic gate insulator 263 may be deposited on the organic semiconducting layer 262, and a sputter resistant layer 264 may be deposited on the organic gate insulator 263. The sputter resistant layer 264 may be UV cured. The sputter resistant layer 264 is arranged to provide resistance to the organic gate insulator 263 and the organic semiconducting layer 262 to sputter damage during subsequent steps.

In FIG. 3G, a frontgate electrode 267 is deposited on the one or more dielectric layers, more specifically on the sputter resistant layer 264. In FIG. 3H, the organic layers 261 are etched in order to provide the OTFT 260 at a particular region on the base layer 240. The etching may be drying etching. The etching stops when the organic material 261 above the base layer 240 (but not below the frontgate electrode 267) has been removed. Since the base layer 240 is continuous during the deposition and etching of the OTFT 260 on the base layer 240, the organic layers 261 may be etched more consistently, thereby reducing the risk of residues remaining during subsequent steps. In particular, the base layer 240 isolates the LED 210 during processing of the OTFT 260.

In FIG. 31, a passivation layer 270 is deposited over the OTFT 260 and the base layer 240. This passivation layer 270 may be referred to as a top passivation layer 270 or a “second” passivation layer 270.

As also shown in FIG. 31, vias are etched through the base layer 240 and the top passivation layer 270 in order to allow electrical connections to the OTFT 260 and the LED 210. In this example, a first passivation layer via 272 is etched through the top passivation layer 270, where continued etching through the base layer 240 provides a first base layer via 242 that allows an electrical connection to be made to the first region 235a of the intermediate layer 235. In a similar manner, a second passivation layer via 274 is etched through the top passivation layer 270, where continued etching through the base layer 240 provides a second base layer via 244 that allows an electrical connection to be made to the second region 235b of the intermediate layer 235. A third passivation layer via 276 is etched through the top passivation layer 270 to allow a connection to the drain electrode 256 of the OTFT 260. A fourth passivation layer via 277 is etched through the top passivation layer 270 to allow a connection to the frontgate electrode 267 of the OTFT 260. Preferably, continued etching of the passivation layer vias 272, 274 to provide the base layer vias 242, 244 occurs in succession and more preferably in the same etching step. Alternatively, the base layer vias 242, 244 may be etched in a separate step to the passivation layer vias 272, 274, 276, 277. For example, the base layer vias 242, 244 may be etched through the base layer 240 before deposition of the top passivation layer 270.

In FIG. 3J, a top contact layer 280 (or “OTFT contact layer”) is deposited onto the top passivation layer 270 and into the vias in order to provide electrical connections through the vias. In this example, the top contact layer 280 provides a connection to the first region 235a of the intermediate layer 235 through the first passivation layer via 272 and the first base layer via 242, thereby providing a connection to the cathode 212 of the LED 210. The top contact layer 280 also provides a connection from the drain electrode 256 of the OTFT 260 to the second region 235b of the intermediate layer 235 through the third passivation layer via 276, the second passivation layer via 274 and the second base layer via 244, thereby connecting the drain electrode 256 to the anode 214 of the LED 210. In this way, the top contact layer 280 provides a connection between the LED 210 and the OTFT 260 through the base layer vias 242, 244, and thus may be referred to as an OTFT contact layer 280. The top contact layer 280 also provides a connection to the frontgate 267 of the OTFT 260 through the fourth passivation layer via 277.

It will be appreciated that other connections may be made in addition to those described above. For example, further vias may be formed to provide a connection to the backgate layer 235c of the OTFT 260 (such as shown in FIG. 4). Furthermore, the backgate layer 235c may be connected to the frontgate 267 or the source electrode 258 of the OTFT 260. As discussed in WO 2022/101644, this may improve voltage stability, lower power consumption and improve bias stress stability. Furthermore, the vias through the top passivation layer 270 may continue through the base layer 240 and also through the middle passivation layer 230 in order to connect to the cathode 212 and anode 214; however, this approach may involve a very long etch time and may need a thick photoresist for etch protection (typically about 150% of the overall via depth). This may limit resolution and may increase the manufacturing cost. Therefore, the connections to the cathode 212 and the anode 214 are preferably provided through the intermediate layer 235.

Optionally, the substrate 205 may be detached from the layers above the substrate 205 (e.g. the cathode layer 212).

The OTFT 260 may be processed, at least partially, using a solution processing technique. For example, the organic semiconducting layer 262 may be deposited using solution processing. Particularly when using a wet technique such as solution processing, the organic layers 261 may be more likely to fall within any vias formed through the base layer 240. Therefore, when using solution processing, it is particularly advantageous to etch the base layer vias 242, 244 after processing of the OTFT 260. Alternatively or additionally, the OTFT 260 may be processed using a vacuum deposition technique.

FIG. 4 shows a more detailed cross section of a display component 3 that may be manufactured using the method discussed in relation to FIGS. 3A to 3J. The display component 3 shares a number of features with the display component 2 formed using the process described above, with corresponding features identified using corresponding reference numerals.

The display component 3 comprises a drive OTFT 360a and switching OTFT 360b, which may be processed in a similar manner as already described. In this example, the drive OTFT 360a has an interdigitated structure, where multiple active channels are provided in order to increase the W value of the OTFT 360a so that the OTFT 360a may provide more current. Furthermore, the display component 3 also includes a V_{DD} terminal 329 which connects to the third region 335c of the intermediate layer 335. The third region 335c of the intermediate layer 335 provides the backgate electrode of both the drive OTFT 360a and the switching OTFT 360b, though it will be appreciated that the OTFTs 360 may have separate backgates that are electrically isolated from each other and/or may be connected elsewhere. A third base layer via 349 and a fifth passivation layer via 379 are provided to allow an electrical connection to be made to the V_{DD} terminal 329 and the third region 335c of the intermediate layer 335, using the top contact layer 380.

A Vₛₛ terminal 322 is also provided, which is electrically connected to the cathode layer 312 through the bottom passivation layer 321. The first base layer via 342 and the first passivation layer via 372 provide the connection to the first region 335a of the intermediate layer 335 in order to connect to the cathode layer 312. Alternatively, these vias 342, 372 and the first region 335a of the intermediate layer 335 may be located elsewhere in order to provide an electrical connection to the cathode layer 312. For example, where the cathode layer 312 is common to multiple LEDs 310 across the display component 3, it may not be necessary to provide electrical connections to the cathode layer 312 for every LED 310.

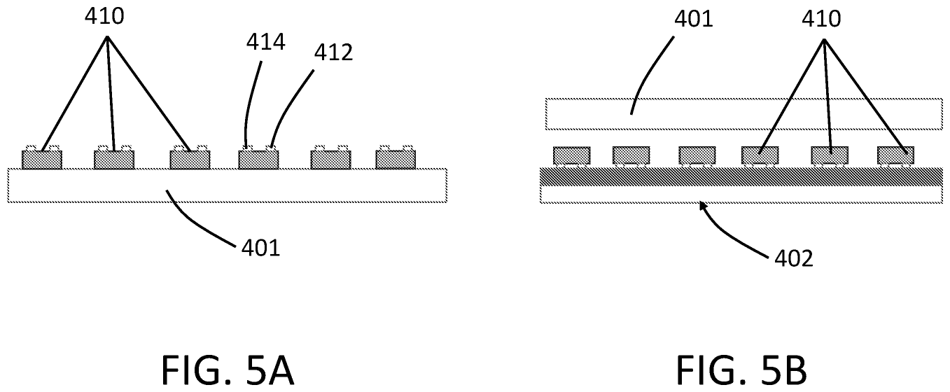

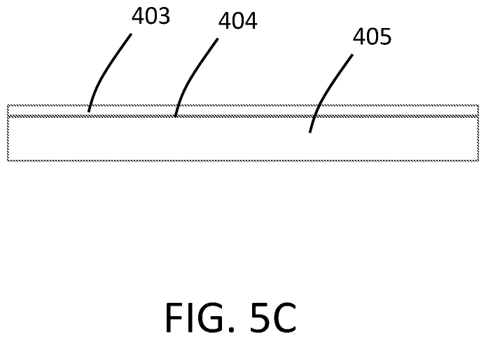

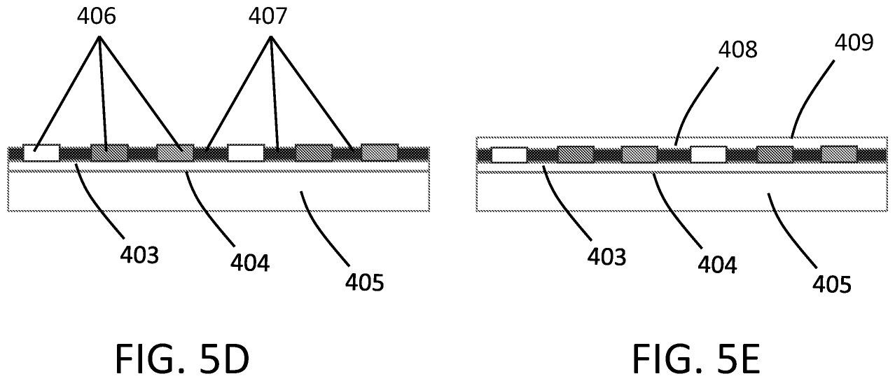

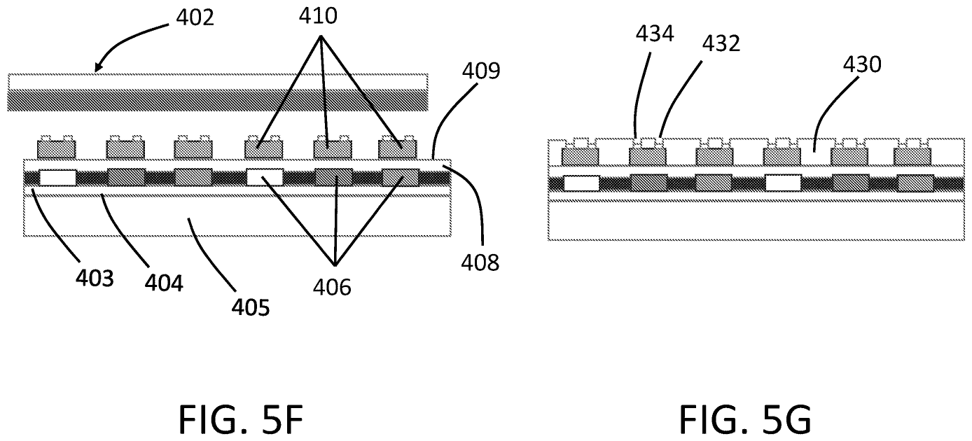

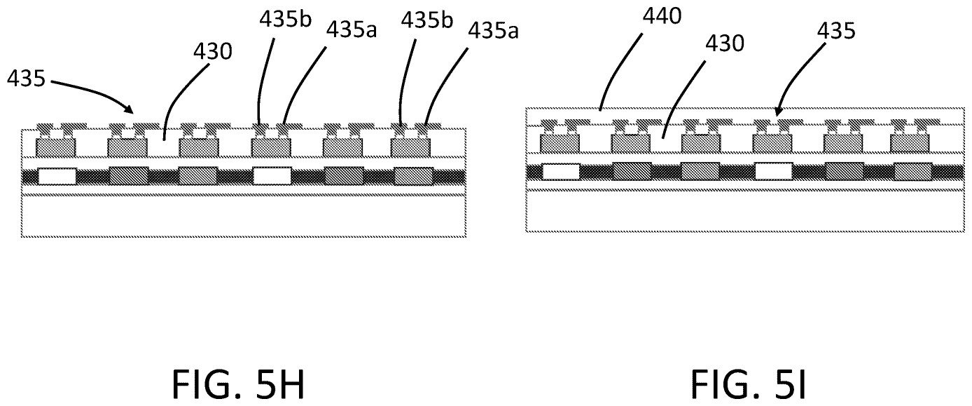

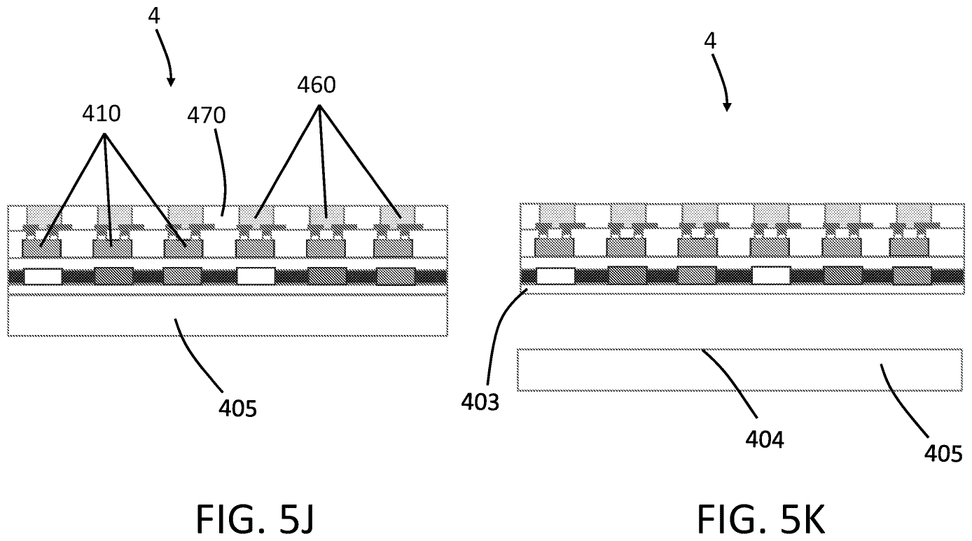

A particular example of a mass transfer method for manufacturing a display component 4 will now be described in relation to FIG. 5A to 5K. A number of the steps and features described in FIG. 5A to 5K correspond to those described in relation to FIGS. 1A to 1P and FIGS. 3A to 3J. Therefore, corresponding features are identified using corresponding reference numerals in order to avoid the need to describe these common features in detail again. It will be appreciated that any details discussed above, such as relating to materials, dimensions, properties of the layers, and/or manufacturing processes may also apply to the following method.

In FIG. 5A, a plurality of LEDs 410 are grown on a source wafer 401, in a similar manner to as already described in relation to FIGS. 1A to 1D. The LEDs 410 may be blue LEDs 410. For clarity, only some of the LEDs 410 have been labelled, and it will be appreciated that any number of LEDs 410 may be grown on the source wafer 401 in order to provide the required number of pixels (or sub-pixels) in the display component 4. Flip-chip contacts are also formed on each of the LEDs 410 to provide a connection to a corresponding cathode 412 and anode 414. The flip-chip contacts shown in FIG. 5A differ from the anode and cathode described in relation to FIGS. 1 and 3 in that the contacts are both provided on the top surface of the LED 410. In FIG. 5B, the LEDs 410 are laser released from the source wafer 401 onto an intermediate film 402. The intermediate film 402 may be referred to as a “transfer substrate” or an “intermediate substrate”. The transfer yield from the source wafer 401 to the transfer substrate 402 can be optimised through use of a strong adhesive on the transfer substrate 402 to ensure the LED 410 sticks upon transfer.

In FIG. 5C, a plastic substrate 403 is laminated onto a glass substrate 405 using a thermal release adhesive 404. Subsequently, as shown in FIG. 5D, quantum-dot (QD) colour conversion materials 406 are processed on top of the plastic substrate 403. The QD colour conversion materials 406 are configured to convert light of a specific wavelength (e.g. blue light from the LEDs) to another colour, such as to provide an RGB display. Optionally, a light blocking layer 407 may be processed between the QD colour conversion materials 406 to reduce cross talk between adjacent LEDs 410. The processing may use photolithography. In FIG. 5E, a planarizing film 408 is formed over the QD colour conversion materials 406 and the light blocking layer 407. The planarizing film 408 may be from 1 to 5 μm thick. An adhesive film 409 is provided over the planarizing film 408.

In FIG. 5F, the LEDs 410 are laser transferred from the intermediate film 402 to the adhesive film 409 on the planarizing film 408. During this step, each LED 410 is aligned with a corresponding QD colour conversion material 406. In this way, each LED 410 may provide a sub-pixel, where a plurality of sub-pixels (e.g. three RGB sub-pixels) provide a colour pixel in the resulting display component 4. Accordingly, the LEDs 410 are deposited on the top surface of the substrate 405 using the intermediate film 402.

In FIG. 5G, a first (or “middle”) passivation layer 430 is deposited over the LEDs 410. Vias 432, 434 are formed through the first passivation layer 430 to allow an electrical connection to be made to the flip-chip contacts of each LED 410. In FIG. 5H, an intermediate (contact) layer 435 is deposited and patterned on the first passivation layer 430. As shown, the intermediate layer 435 includes a first region 435a connected to the cathode 412 of the LED 410 and a second region 435b connected to the anode 414 of the LED 410. In FIG. 51, a base layer 440 is deposited over the first passivation layer 430 and the intermediate layer 435. While not shown in FIG. 5H, a third region of the intermediate layer 435 may provide the backgate of each OTFT 460.

In FIG. 5J, a plurality of OTFTs 460 are processed. While FIG. 5J depicts a single OTFT 460 for each of the LEDs 410, it will be appreciated that more than one OTFT 460 may be provided for each LED 410 (such as a switching OTFT and a drive OTFT as discussed in relation to FIG. 4). A top passivation layer 470 is also deposited. While not shown in detail in FIG. 5J, it will be appreciated that other elements, such as vias, and contact layers may also be provided, in a similar manner to already described in relation to FIG. 3A to 3J, and/or FIG. 4.

Optionally, in FIG. 5K, the glass substrate 405 may be removed from the layers above the glass substrate 405. The glass substrate 405 may be separated from the plastic substrate 403 using the thermal release adhesive 404. By removing the glass substrate 405, it may be possible to provide a flexible display component 4.

Use of a transfer substrate 402 followed by deposition of OTFT 460 to form a monolithic display component 4 can be advantageous since only the required amount of LED source wafer 401 is used for light emission. The display component 4 may be considered as monolithic in the sense that the OTFTs 460 are grown on the substrate 405 containing the LEDs 410 rather than the LEDs being transferred onto a substrate containing the OTFTs 460.

While the foregoing is directed to exemplary embodiments of the present invention, it will be understood that the present invention is described herein purely by way of example, and modifications of detail can be made within the scope of the invention. Furthermore, one skilled in the art will understand that the present invention may not be limited by the embodiments disclosed herein, or to any details shown in the accompanying figures that are not described in detail herein or defined in the claims. Indeed, such superfluous features may be removed from the figures without prejudice to the present invention.

Moreover, other and further embodiments of the invention will be apparent to those skilled in the art from consideration of the specification, and may be devised without departing from the basic scope thereof, which is determined by the claims that follow.

1. A method of fabricating a monolithic micro-LED display component, the method comprising:
depositing an LED on a top surface of a substrate;
depositing a base layer over the LED, the base layer forming a planar layer isolating the LED;
processing an organic thin film transistor, OTFT, on the base layer by depositing source and drain electrodes and an active channel comprising an organic semiconducting layer; and after processing of the OTFT,
etching a base layer via, the base layer via comprising a via through the base layer to allow a connection between the LED and the OTFT.

2. The method of claim 1, wherein the OTFT is processed at a region on the base layer that overlaps the LED, at least partially.

3. The method of claim 1, wherein prior to depositing the base layer, the method further comprises:
depositing a planarization layer over the LED;
etching a planarization layer via through the planarization layer; and
depositing an intermediate contact layer on the planarization layer, such that the intermediate contact layer is connected to the LED through the planarization layer via; the method further comprising depositing the base layer over the planarization layer and intermediate contact layer.

4. The method of claim 3, wherein the step of etching the base layer via comprises etching a via through the base layer to provide a connection to the intermediate contact layer, the method further comprising depositing an OTFT contact layer providing a connection between the OTFT and the intermediate contact layer, such that the OTFT is connected to the LED through the intermediate contact layer.

5. The method of claim 4, further comprising:
depositing a passivation layer over the base layer prior to etching the base layer via;
etching one or more passivation layer vias through the passivation layer;
wherein continued etching of at least one passivation layer via provides the base layer via; and
wherein the OTFT contact layer is deposited into the passivation layer vias to connect the LED to the OTFT through the intermediate contact layer.

6. The method of claim 3, wherein the planarization layer has a thickness such that a portion of the planarization layer that is above the LED is at least 0.5 μm thick.

7. The method of claim 3, wherein the intermediate contact layer provides a backgate layer of the OTFT.

8. The method of claim 3, wherein the intermediate contact layer comprises a first region connected to an anode of the LED by a first planarization layer via, and a second region connected to a cathode of the LED by a second planarization layer via.

9. The method of claim 3, wherein the intermediate contact layer and/or a backgate layer provide a reflective layer such that light emitted by the LED in an upward direction is reflected by the reflective layer in a downward direction corresponding to a bottom surface of the LED.

10. The method of claim 1, wherein processing the OTFT comprises depositing one or more dielectric layers on the organic semiconducting layer.

11. The method of claim 10, wherein processing the OTFT further comprises depositing a frontgate metal on the one or more dielectric layers.

12. The method of claim 1, wherein processing the OTFT further comprises at least partially etching away one or more organic layers above the base layer.

13. The method of claim 1, further comprising:
depositing a passivation layer over the OTFT and the base layer, and
etching said passivation layer to form one or more passivation layer vias.

14. The method of claim 13, wherein the base layer via is formed by continuing etching of at least one of the passivation layer vias through the base layer.

15. The method of claim 13, further comprising depositing an OTFT contact layer into the one or more passivation layer vias.

16. The method of claim 1, further comprising growing the LED on a source wafer, and subsequently transferring the LED from the source wafer to the substrate using an intermediate substrate.

17. The method of claim 1, further comprising detaching the substrate from the layers above the substrate.

18. The method of claim 1, wherein the OTFT is processed, at least partially, using a solution processing technique.

19. A monolithic micro-LED display component, comprising:
an LED having a top surface and an opposing bottom surface;
a planar base layer formed above the top surface of the LED;
an organic thin film transistor, OTFT, processed at least partially on an upper surface of the planar base layer;
a passivation layer deposited on the OTFT; and
a base layer via etched through both the base layer and the passivation layer, whereby to allow an electrical connection between the LED and the OTFT.

20. The monolithic micro-LED display component of claim 19, further comprising an intermediate contact layer formed on a lower surface of the planar base layer and electrically connected to the LED, wherein the base layer via is connected to the intermediate contact layer.
